(19) United States
(12) Patent Application Publication
(10) Pub. No.: US 2014/0035446 A1
(43) Pub. Date: Feb. 6, 2014

(54) STRUCTURAL FASTENING MECHANISM FOR ELECTRONIC DEVICE ENCLOSURE

(71) Applicants: YUN-LUNG CHEN, Tu-Cheng (TW); CHUNG CHAI, Tu-Cheng (TW); ZHI-QIANG LI, Wuhan City (CN); GUANG-BIN YIN, Wuhan City (CN)

(72) Inventors: YUN-LUNG CHEN, Tu-Cheng (TW); CHUNG CHAI, Tu-Cheng (TW); ZHI-QIANG LI, Wuhan City (CN); GUANG-BIN YIN, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/571,736

(22) Filed: Aug. 10, 2012

(30) Foreign Application Priority Data
Aug. 1, 2012 (CN) 201210270401X

(51) Int. Cl. H05K 5/02; F16B 2/20

(52) U.S. Cl. 312/223.1; 24/530

(57) ABSTRACT

An electronic device enclosure includes a base, a side plate, and a locking member. The base comprises a rear wall defining two through holes. Two stopping portions are located on the rear wall. The side plate comprises a side piece. The locking member comprises a resilient portion and two blocking portions located on the resilient portion. The resilient portion is secured to the side piece. Each of the two blocking portions extends through each of the two through holes to engage with each of the two stopping portions. The resilient portion elastically deforms to move the two blocking portions towards each other, to disengage each of the two blocking portions from each of the two stopping portions.

### BACKGROUND

1. Technical Field

The present disclosure relates to enclosures, and particularly to an electronic device enclosure with a structural fastening mechanism.

2. Description of Related Art

An electronic device enclosure, such as a personal computer case, may include a base and a side plate. The base comprises a bottom plate, two sidewalls, a rear plate, and a front plate. The two sidewalls extend from opposite edges of the bottom plate. The rear plate and the front plate extend from the other opposite edges of the bottom plate. The two sidewalls, the rear plate, and the front plate cooperatively define an opening. The side plate may be configured to be secured to the base with a plurality of screws. However, the use of screws is laborious and time-consuming.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device enclosure comprising a base and a side plate.

FIG. 2 is an exploded view of a locking member and the side plate of FIG. 1.

FIG. 3 is an assembled view of the items of FIG. 1.

FIG. 4 is a cross-sectional view of FIG. 3, taken along line IV-IV, when the tongues are engaged with the stopping portions.

FIG. 5 is similar to FIG. 4, but the tongues are disengaged from the stopping portions.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

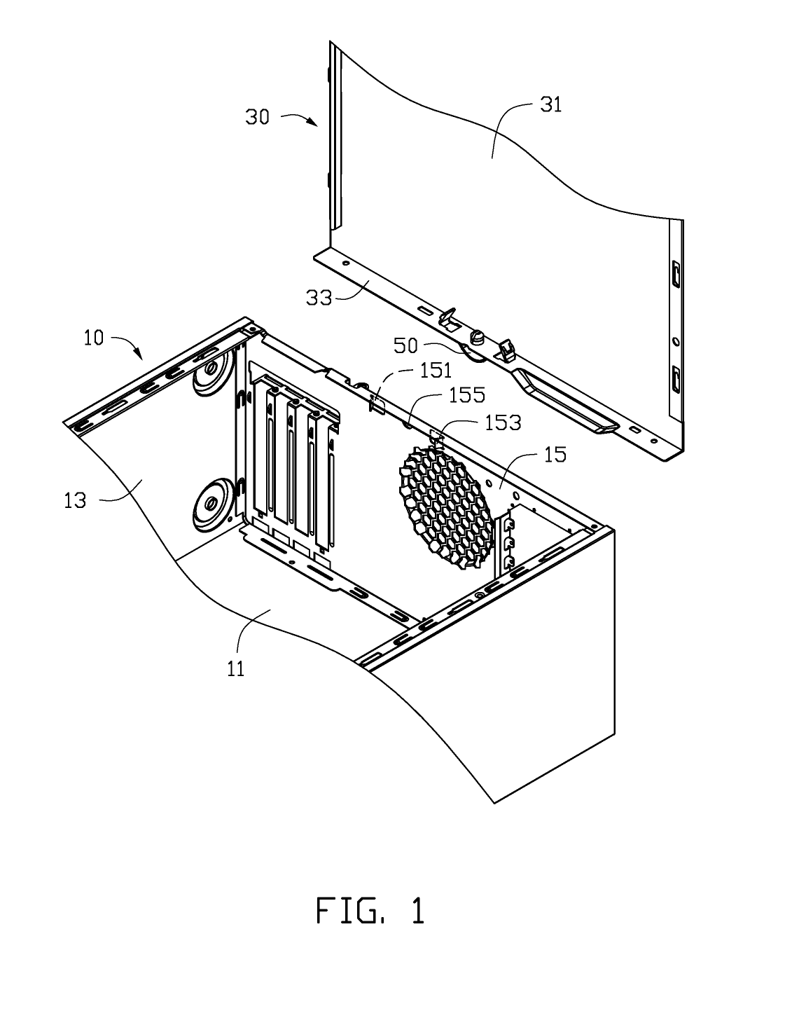

Referring to FIG. 1, an electronic device enclosure in accordance with an embodiment includes a base 10, a side plate 30, and a locking member 50 attached to the side plate 30.

The base 10 includes a bottom wall 11, two sidewalls 13, a front wall (not shown), and a rear wall 15. The two sidewalls 13 extend from opposite edges of the bottom wall 11. The front wall and the rear wall 15 extend from another opposite edges of the bottom wall 11. In one embodiment, the two sidewalls 13 are substantially parallel to each other and perpendicular to the bottom wall 11, and the front wall is substantially parallel to the rear wall 15 and perpendicular to the bottom wall 11. The two sidewalls 13, the front wall and the rear wall 15 cooperatively define a space or void.

The rear wall 15 defines two through holes 151. An installation hole 155, located between the two through holes 151, is defined in the rear wall 15. Two stopping portions 153 are located on an inner side of the rear wall 15. Each of the two stopping portions 153 are canted inwards less than ninety degrees from an edge of each of the two through holes 151. In one embodiment, an obtuse angle is defined between the rear wall 15 and each of the two stopping portions 153.

The side plate 30 includes a main body 31 and a side piece 33 connected to the main body 31. The side piece 33 extends from an edge of the main body 31 and is substantially perpendicular to the main body 31. The side piece 33 defines two latching holes 331. Each of the two latching holes 331 includes a wide portion 3311 and a narrow portion 3313 in communication with the wide portion 3311. A width of the wide portion 3311 is greater than a width of the narrow portion 3313. A positioning post 333, located between the two latching holes 331, is located on an inner side of the side piece 33. The positioning post 333 defines a positioning hole 3331 extending to the side piece 33.

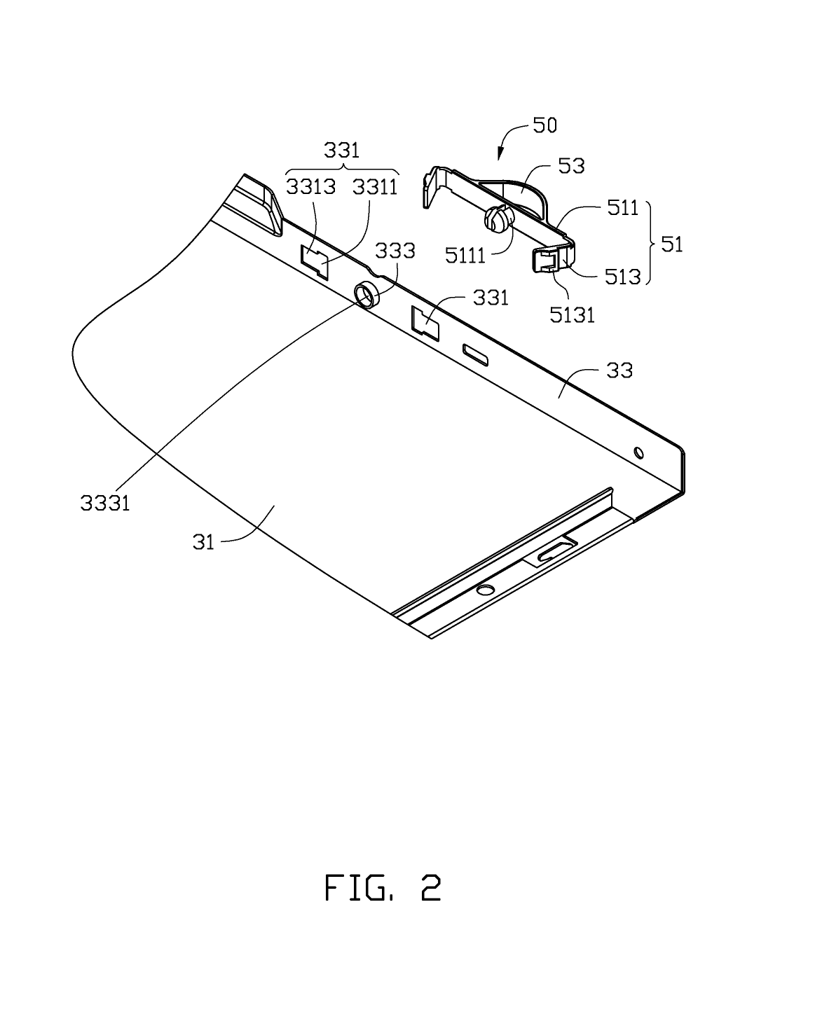

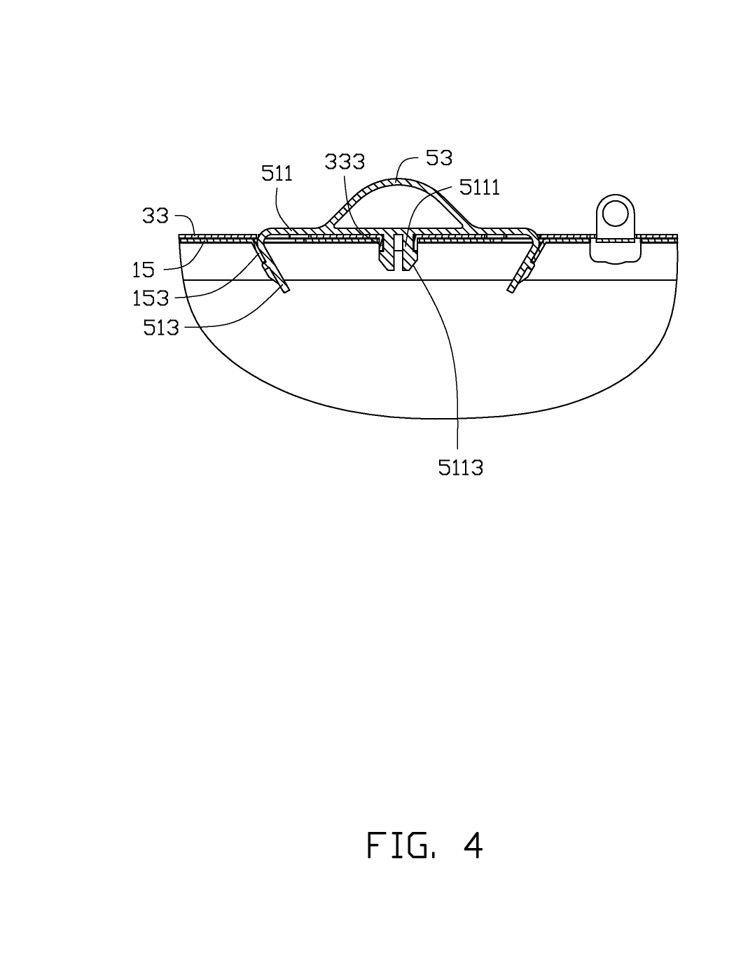

Referring to FIGS. 2 and 4, the locking member 50 includes a mounting portion 51 and an operating portion 53 located on one side of the mounting portion 51. The operating portion 53 has an arc-shaped cross-section suitable for being gripped by a finger and thumb. The mounting portion 51 includes a resilient portion 511 and two blocking portions 513 located on opposite ends of the resilient portion 511. Two hooks 5111, opposite to the operating portion 53, are located on the resilient portion 511 in middle of the two blocking portions 513. The two blocking portions 513 obliquely extend from the resilient portion 511, at an angle substantially similar to that of the stopping portions 153. An obtuse angle is defined between the resilient portion 511 and each of the two blocking portions 513. Each of the two blocking portions 513 includes a tongue 5131 located on an outside surface of each of the two blocking portion 513.

Referring to FIG. 4, in assembly of the locking member 50 to the side plate 30, the locking member 50 is placed on outside of the side piece 33. The two blocking portions 513 are squeezed together and inserted into the wide portions 3311 of the two latching holes 331. The two blocking portions 513 are released to engage into the narrow portions 3313. The two hooks 5111 extend through the positioning hole 3331 to engage with the positioning post 333. The locking member 50 is thereby installed on the side plate 30.

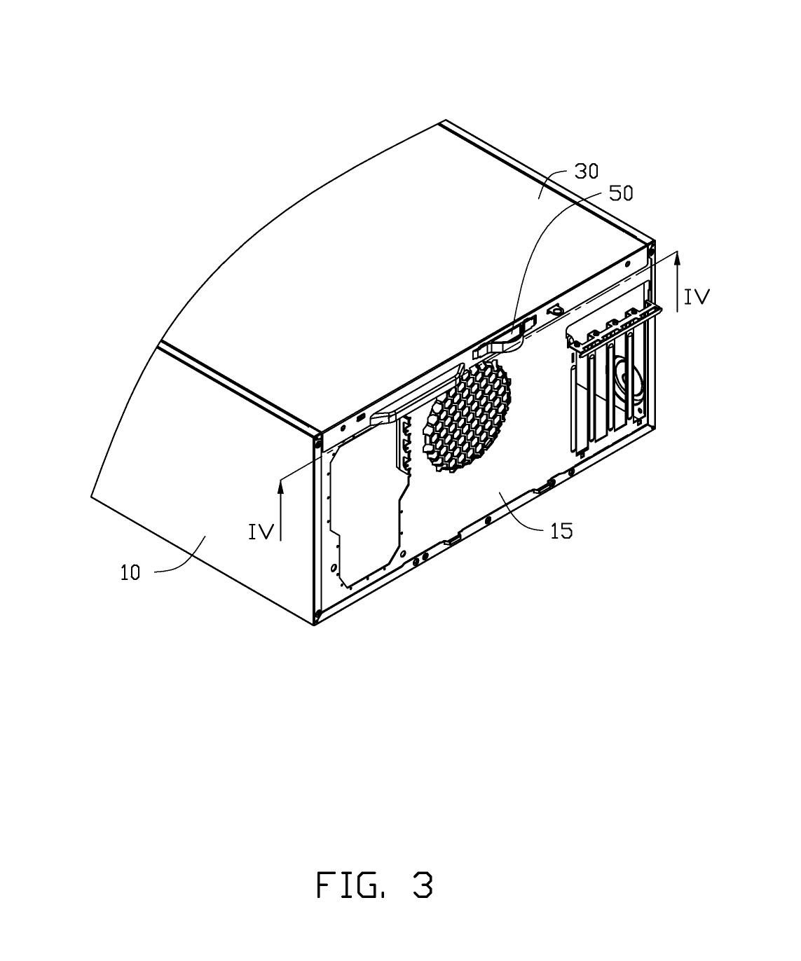

Referring to FIG. 3, in assembly of the side plate 30 to the rear wall 15, the two blocking portions 513 are respectively inserted into the two through holes 151 of the base 10. The two stopping portions 153 bias the two blocking portions 513 to resiliently deform and move towards each other. The side plate 30 is moved along a first direction towards the rear wall 15, until the two blocking portions 513 are free to restore and engage with the two stopping portions 153. In one embodiment, the two blocking portions 513 restore to engage the tongues 5131 with the stopping portions 153. The positioning post 333 goes through the installation hole 155. The side plate 30 is thus installed on the base 10.

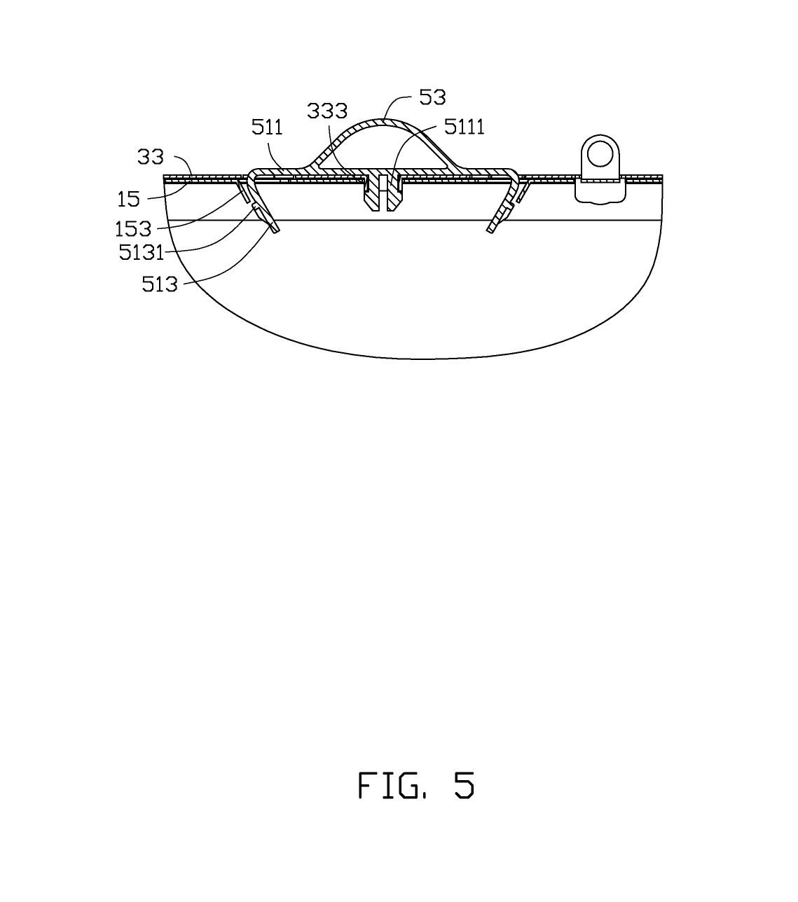

Referring to FIG. 5, in disassembly of the side plate 30, the operating portion 53 is pulled along a second direction opposite to the first direction which deforms the resilient portion 511. The resilient portion 511 allows the two blocking portions 513 to move together and so reduce the distance between them. The two blocking portions 513 are moved towards the narrow portions 3313, until the tongues 5131 disengage from the stopping portions 153. The side plate 30 can thus be removed from the base 10.

Even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device enclosure comprising:
a base, the base comprising a rear wall defining two through holes, and two stopping portions located on the rear wall;
a side plate, the side plate comprising a side piece; and
a locking member, the locking member comprising a resilient portion and two blocking portions, and the resilient portion secured to the side piece;
wherein each of the two blocking portions extends through each of the two through holes to engage with each of the two stopping portions; and the resilient portion is elastically deformable to move the two blocking portions towards each other, to disengage each of the two blocking portions from each of two stopping portions.

2. The electronic device enclosure of claim 1, wherein the side piece defines two latching holes, and each of the two blocking portions is engaged in each of the two latching holes.

3. The electronic device enclosure of claim 1, wherein a tongue is located on each of the two blocking portions, and the tongue is engaged with each of the two stopping portions.

4. The electronic device enclosure of claim 2, wherein each of the two latching holes comprises a wide portion and a narrow portion in communication with the wide portion, and the resilient portion is elastically deformable to move each of the two blocking portions from the narrow portion to the wide portion.

5. The electronic device enclosure of claim 2, wherein the two blocking portions obliquely extend from opposite ends of the resilient portion, and an acute angle is defined between the resilient portion and each of the two blocking portions.

6. The electronic device enclosure of claim 4, wherein a width of the wide portion is greater than a wide of the narrow portion.

7. The electronic device enclosure of claim 2, wherein two hooks are located on the resilient portion, a positioning hole is defined in the side piece, and the two hooks are engaged in the positioning hole.

8. The electronic device enclosure of claim 7, wherein the locking member further comprises an operating portion, and the operating portion and the two hooks are located on opposite sides of the resilient portion.

9. The electronic device enclosure of claim 8, wherein the operating portion has an arc-shaped cross-section substantially perpendicular to the resilient portion.

10. The electronic device enclosure of claim 1, wherein each of the two stopping portions obliquely extends from an edge of each of the two through holes, and an acute angle is defined between the rear wall and each of the two stopping portions.

11. A structural fastening mechanism comprising:
a locking member, the locking member comprising a resilient portion and two blocking portions located on the resilient portion, the resilient portion secured to a side plate; wherein the two blocking portions are capable of being engaged with a base, for securing the side plate to the base, and the resilient portion is elastically deformable to move the two blocking portions towards each other, to disengage the two blocking portions from the base.

12. The structural fastening mechanism of claim 11, wherein the two blocking portions extend from opposite ends of the resilient portion, and an acute angle is defined between the resilient portion and each of the two blocking portions.

13. The structural fastening mechanism of claim 11, wherein a tongue is located on each of the two blocking portions, and the tongue is configured to engage with the base.

14. The structural fastening mechanism of claim 11, wherein two hooks are located on the resilient portion, and the two hooks are configured to engage with the side plate.

15. The structural fastening mechanism of claim 14, wherein the two hooks is located in middle of the two blocking portions.

16. The structural fastening mechanism of claim 14, wherein the locking member further comprises an operating portion, and the operating portion, opposite to the two hooks, is located on the resilient portion, for biasing the resilient portion.

17. The structural fastening mechanism of claim 16, wherein the operating portion has a cross-section substantially perpendicular to the resilient portion, and the cross-section is substantially arc-shaped.
